(19) United States
(12) Patent Application Publication
(10) Pub. No.: US 2016/0240666 A1
(43) Pub. Date: Aug. 18, 2016

(54) SEMICONDUCTOR DEVICE AND MANUFACTURING METHOD THEREOF

(71) Applicant: KABUSHIKI KAISHA TOSHIBA, Tokyo (JP)

(72) Inventors: Toshitaka MIYATA, Kawasaki Kanagawa (JP); Yoshiyuki KONDO, Yokohama Kanagawa (JP)

(73) Assignee: KABUSHIKI KAISHA TOSHIBA, Tokyo (JP)

(21) Appl. No.: 14/717,526

(22) Filed: May 20, 2015

Related U.S. Application Data
(60) Provisional application No. 62/117,865, filed on Feb. 18, 2015.

(51) Int. Cl. H01L 29/78; H01L 29/66; H01L 29/08; H01L 29/423; H01L 29/40

(52) U.S. Cl. CPC H01L 29/7827; H01L 29/42368; H01L 29/401; H01L 29/0847; H01L 29/66545; H01L 29/66666

(57) ABSTRACT

A device includes a first and a second semiconductor-layer. The second semiconductor-layer is on the first semiconductor-layer, and has a first and a second side-surface. A first gate-dielectric is on the first semiconductor-layer. A second gate-dielectric is on the first side-surface. A gate has a bottom surface facing the first semiconductor-layer, and a third side-surface facing the first side-surface. A first diffusion-layer of a first conductivity-type is in a region in the second semiconductor-layer on a side of the second side-surface, and forms a junction with a region in the second semiconductor-layer on a side of the first side-surface. A silicide is on the second side-surface. A source of the first conductivity-type is in the first semiconductor-layer on a side of the third side-surface. A drain layer of a second conductivity-type is in the first semiconductor-layer on a side of a fourth side-surface of the gate electrode.

### CROSS REFERENCE TO RELATED APPLICATIONS

This application is based upon and claims the benefit of priority from the prior U.S. Provisional Patent Application No. 62/117,865, filed on Feb. 18, 2015, the entire contents of which are incorporated herein by reference.

### FIELD

The embodiments of the present invention relate to a semiconductor device and manufacturing method thereof.

### BACKGROUND

In recent years, a TFET (Tunnel Field-Effect Transistor) using a quantum-mechanical effect of electrons has been developed. The TFET is brought to a conduction state by BTBT (Band To Band Tunneling) occurring between a source layer and a channel portion.

A PIN-type TFET being a general TFET is brought to a conduction state by BTBT occurring at a source end portion. However, it is difficult to obtain a sufficiently-large on-current only by the BTBT at the source end portion. A TFET that causes BTBT in a surface region of a semiconductor layer located below a gate electrode thus has been developed. Accordingly, the area of a region in which the BTBT occurs is enlarged and the on-current is increased.

However, even with this TFET, the on-current is still insufficient and a TFET that enables a larger on-current to flow is demanded.

### BRIEF DESCRIPTION OF THE DRAWINGS

FIG. 1 is a schematic cross-sectional view showing an example of a configuration of a P-type TFET 100 according to a first embodiment;

FIGS. 2A to 6B are cross-sectional views showing an example of a manufacturing method of the P-type TFET 100 according to the first embodiment;

FIGS. 7A to 11 are cross-sectional views showing an example of the manufacturing method of the TFET 100 according to the second embodiment; and

FIGS. 12A to 13 are cross-sectional views showing an example of the manufacturing method of the TFET 100 according to the third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor layer on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a first semiconductor layer and a second semiconductor layer. The second semiconductor layer is provided on the first semiconductor layer and has a first side surface and a second side surface on an opposite side to the first side surface. A first gate dielectric film is provided on the first semiconductor layer. A second gate dielectric film is provided on the first side surface of the second semiconductor layer. A gate electrode has a bottom surface facing a surface of the first semiconductor layer via the first gate dielectric film, and a third side surface facing the first side surface of the second semiconductor layer via the second gate dielectric film. A first diffusion layer of a first conductivity type is provided in a region in the second semiconductor layer on a side of the second side surface, and forms a junction part with a region in the second semiconductor layer on a side of the first side surface. A silicide layer is provided on the second side surface of the second semiconductor layer and connects to the first diffusion layer. A source layer of the first conductivity type is provided in the first semiconductor layer on a side of the third side surface of the gate electrode, and is electrically connected to the first diffusion layer and the silicide layer. A drain layer of a second conductivity type is provided in the first semiconductor layer on a side of a fourth side surface of the gate electrode on an opposite side to the third side surface.

### First Embodiment

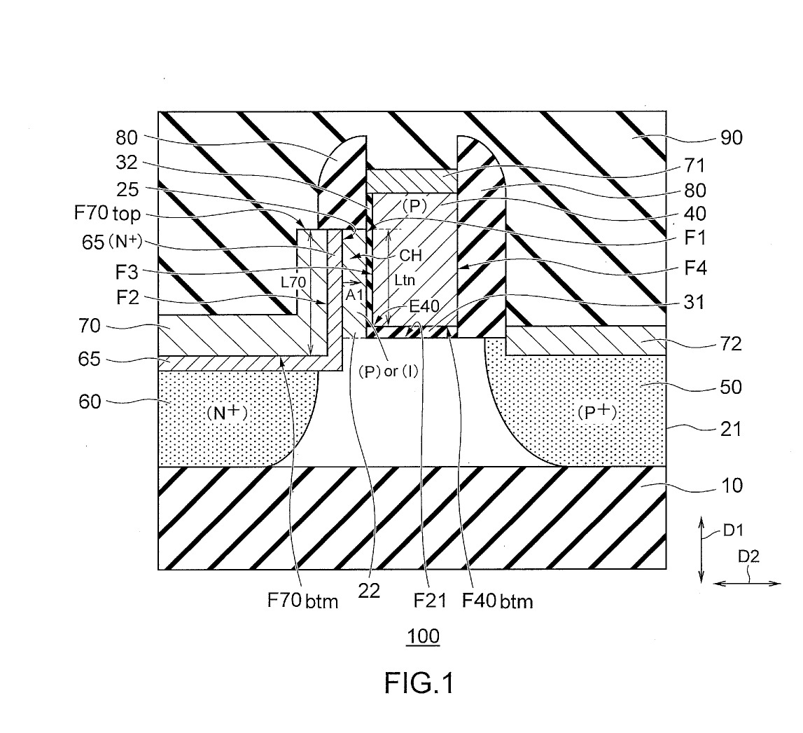

FIG. 1 is a schematic cross-sectional view showing an example of a configuration of a P-type TFET 100 according to a first embodiment. The TFET 100 can be used for a logic semiconductor integrated circuit such as a microprocessor or an ASIC (Application Specific Integrated Circuit).

The TFET 100 includes a BOX (Buried Oxide) layer 10, a first semiconductor layer 21, a second semiconductor layer 22, a first gate dielectric film 31, a second gate dielectric film 32, a gate electrode 40, a drain layer 50, a source layer 60, a high-concentration layer 65, silicide layers 70 to 72, a sidewall film 80, and an interlayer dielectric film 90.

The first semiconductor layer 21 is a SOI (Silicon On Insulator) layer provided on the BOX layer 10. The first semiconductor layer 21 can be a SOI layer of a SOI substrate and also can be a SiGe layer of a SiGe-OI substrate, a Ge layer of a Ge-OI substrate, a silicon layer formed of a silicon substrate, or a semiconductor layer using a III-V compound semiconductor substrate. Alternatively, the first semiconductor layer 21 can be a semiconductor layer epitaxially grown on an arbitrary substrate.

The second semiconductor layer 22 is provided on the first semiconductor layer 21 and extends in a direction (hereinafter, also “direction D1”) substantially orthogonal to a surface F21 of the first semiconductor layer 21. Therefore, the second semiconductor layer 22 has a so-called fin shape and a bottom portion thereof is electrically connected to the first semiconductor layer 21. The second semiconductor layer 22 has a first side surface F1 and a second side surface F2 on the opposite side to the first side surface F1. The second semiconductor layer 22 can be, for example, a semiconductor material epitaxially grown on the first semiconductor layer 21. The material of the second semiconductor layer 22 can be the same as that of the first semiconductor layer 21 or can be different therefrom.

The first gate dielectric film 31 is an insulating film provided on the surface F21 of the first semiconductor layer 21 and is formed of, for example, a silicon dioxide film or a dielectric material having a higher dielectric constant than that of the silicon dioxide film.

The second gate dielectric film 32 is provided on the first side surface F1 of the second semiconductor layer 22. Therefore, the second gate dielectric film 32 extends in the direction D1 along the first side surface F1 of the second semiconductor layer 22. The second gate dielectric film 32 is formed of a silicon dioxide film or a dielectric material having a higher dielectric constant than that of the silicon dioxide film similarly to the first gate dielectric film 31. The material of the second gate dielectric film 32 can be the same as that of the first gate dielectric film 31 or can be different therefrom. A film thickness of the second gate dielectric film 32 is preferably equal to or smaller than that of the first gate dielectric film 31. This suppresses parasitic BTBT occurring in the first semiconductor layer 21 below a bottom surface F40btm of the gate electrode 40 and causes BTBT to be more likely to occur in a channel region CH of the second semiconductor layer 22.

The gate electrode 40 has the bottom surface F40btm facing the surface F21 of the first semiconductor layer 21 with the first gate dielectric film 31 interposed therebetween (or via the first gate dielectric film 31), and a third side surface F3 facing the first side surface F1 of the second semiconductor layer 22 with the second gate dielectric film 32 interposed therebetween (or via the second gate dielectric film 32). The gate electrode 40 is formed of, for example, P-type doped polysilicon.

The high-concentration layer 65 serving as a first diffusion layer is provided in a region of the second semiconductor layer 22 on the side of the second side surface F2. Therefore, the high-concentration layer 65 extends in the direction D1 along the second side surface F2. The high-concentration layer 65 is provided also in a surface region of the source layer 60. Therefore, the high-concentration layer 65 extends also in a direction (hereinafter, also “direction D2”) substantially parallel to the surface F21 of the first semiconductor layer 21 in the surface region of the source layer 60. The high-concentration layer 65 contains N-type impurities (arsenic, for example) at a higher concentration than that of the source layer 60. The high-concentration layer 65 is formed by segregating the impurities during formation of the silicide layer 70. Therefore, in the high-concentration layer 65, the impurity concentration is high in the vicinity of the second side surface F2 relatively near the silicide layer 70 and decreases from the second side surface F2 toward the first side surface F1. When the impurities are to be segregated, it is preferable that the N-type impurities contained in the high-concentration layer 65 be arsenic.

A region (hereinafter, also “channel region CH”) in the second semiconductor layer 22 on the side of the first side surface F1 does not include the high-concentration layer 65 and is an intrinsic semiconductor layer (an I layer) or a low-concentration P-type semiconductor layer. Accordingly, the region in the second semiconductor layer 22 on the side of the first side surface F1 and the high-concentration layer 65 are in contact with each other in the second semiconductor layer 22 to form a junction part 25. The junction part 25 forms a PN junction or a PI (P-Intrinsic) junction and extends along the second side surface F2 of the second semiconductor layer 22.

The silicide layer 70 is provided on the second side surface F2 of the second semiconductor layer 22. Therefore, the silicide layer 70 extends in the direction D1 along the second side surface F2. The silicide layer 70 is provided also on the surface of the source layer 60. Therefore, in the surface region of the source layer 60, the silicide layer 70 extends in the direction D2. The silicide layer 70 is, for example, a metal silicide obtained by a reaction between a metal such as Ni, Co, or Ti and silicon. The silicide layer 71 is provided on the gate electrode 40. The silicide layer 72 is provided on the drain layer 50. The silicide layers 71 and 72 are formed of the same material as that of the silicide layer 70.

The high-concentration layer 65 and the silicide layer 70 bend in the vicinity of a lower end of the gate electrode 40 on the source side and are continuous from the second side surface F2 of the second semiconductor layer 22 to the surface of the source layer 60.

A length L70 along the second side surface F2 from a bottom surface F70btm of the silicide layer 70 to a top surface F70top of the silicide layer 70 (a top surface of the second semiconductor layer 22) is larger than a length Ltn along the third side surface F3 from the bottom surface F40btm of the gate electrode 40 to the height of the top surface F70top of the silicide layer 70 (a length in the direction D1 of the channel region CH where BTBT occurs). The length L70 can be also said to be a length in the direction D1 of the silicide layer 70 along the second side surface F2 of the second semiconductor layer 22. The length Ltn can be also said to be the length in the direction D1 of the channel region CH where BTBT occurs. Because the top surface F70top of the silicide layer 70 is at a height substantially equal to the top surface of the second semiconductor layer 22, the bottom surface F70btm of the silicide layer 70 is at a depth (height) equal to the bottom surface F40btm of the gate electrode 40 or a deeper (lower) position. Accordingly, parasitic BTBT occurring at a lower end E40 of the gate electrode 40 on the source side can be suppressed as described later.

The P-type drain layer 50 is provided in the first semiconductor layer 21 on the side of a fourth side surface F4 of the gate electrode 40 on the opposite side to the third side surface F3. The drain layer 50 is a diffusion layer having P-type impurities at a higher concentration than the impurity concentration of the first semiconductor layer 21.

The N-type source layer 60 is provided in the first semiconductor layer 21 on the side of the third side surface F3 of the gate electrode 40. The N-type source layer 60 is electrically connected to the high-concentration layer 65 and the silicide layer 70.

The sidewall film 80 is provided to cover the fourth side surface F4 of the gate electrode 40. The sidewall film 80 is also provided at an upper portion of the third side surface F3 (on the top surfaces of the second semiconductor layer 22 and the silicide layer 70). The sidewall film 80 is formed of an insulating material such as a silicon dioxide film or a silicon nitride film.

The interlayer dielectric film 90 is provided to cover the silicide layers 70 to 72. The interlayer dielectric film 90 is formed of an insulating material such as a silicon dioxide film (a TEOS (Tetraethylorthosilicate) film, for example).

Although not shown in FIG. 1, a wiring structure including contacts, metal wires, and the like is provided on the gate electrode 40, the drain layer 50, and the source layer 60.

The P-type TFET 100 becomes an on-state when a gate voltage is lower than a threshold voltage with reference to a source voltage and becomes an off-state when a gate voltage is higher than the threshold voltage. For example, when a positive voltage is applied to the source, the P-type TFET 100 is brought to an on-state by setting the gate voltage to 0 volt and is brought to an off-state by setting the gate voltage to a power supply voltage (1 volt, for example).

When the gate electrode 40 is at a voltage higher than the threshold voltage, the TFET 100 is in an off-state. At that time, while quite a small current (an off-leak current) caused by a reverse bias flows through the junction part 25 between the high-concentration layer 65 and the channel region CH of the second semiconductor layer 22, the TFET 100 is substantially in an off-state. The channel region CH is a region of the second semiconductor layer 22 located between the high-concentration layer 65 and the second gate dielectric film 32.

When the gate voltage is lowered with respect to the source voltage, the channel region CH starts depleting. At that time, a depletion layer extends from the junction part 25 toward the first side surface F1. When the gate voltage becomes lower than the threshold voltage, BTBT occurs in the channel region CH. The BTBT in the channel region CH can occur in the channel region CH corresponding to the entire facing surface between the third side surface F3 of the gate electrode 40 and the high-concentration layer 65. Accordingly, the TFET 100 enables a relatively-large on-current to flow. At that time, the on-current is generated in a direction of an arrow A1 in the channel region CH and flows through the first semiconductor layer 21 located below the bottom surface F40btm of the gate electrode 40 to the drain layer 50.

As described above, the TFET 100 according to the first embodiment has the channel region CH and the high-concentration layer 65 in the second semiconductor layer 22 extending in the direction D1 from the surface F21 of the first semiconductor layer 21. Therefore, the junction part 25 between the channel region CH and the high-concentration layer 65 also extends in the direction D1 from the surface F21 of the first semiconductor layer 21. The high-concentration layer 65 is formed by segregating the impurities during a silicide process and has an impurity concentration equal to or higher than that of the source layer 60. Therefore, the junction part 25 has quite a steep impurity concentration gradient. Accordingly, the depletion layer is likely to extend in the channel region CH and BTBT in the channel region CH is likely to occur. Because the BTBT in the channel region CH occurs in a relatively-wide region corresponding to the entire facing surface between the third side surface F3 of the gate electrode 40 and the high-concentration layer 65, the TFET 100 enables a relatively-large on-current to flow therethrough.

In the first embodiment, the silicide layer 70 is provided to be in contact not only with the high-concentration layer 65 located on the source layer 60 but also with the high-concentration layer 65 located on the second side surface F2 of the second semiconductor layer 22. By thus forming the silicide layer 70 also on the second side surface F2 of the second semiconductor layer 22, the impurities in the high-concentration layer 65 can be segregated to set the impurity concentration of the high-concentration layer 65 quite high. Provision of the silicide layer 70 on the second side surface F2 of the second semiconductor layer 22 enables a source electrode (not shown) to be electrically connected to the high-concentration layer 65 located on the second side surface F2 of the second semiconductor layer 22 with a low resistance. Accordingly, BTBT in the channel region CH becomes more likely to occur. Furthermore, a current easily flows in the channel region CH and thus an on-current can be further increased.

Furthermore, according to the first embodiment, the film thickness of the second gate dielectric film 32 is equal to or smaller than that of the first gate dielectric film 31. This enables an electric field from the gate electrode 40 to be applied to the channel region CH of the second semiconductor layer 22 more easily than to the first semiconductor layer 21 located under the second semiconductor layer 22. Parasitic BTBT occurring in the first semiconductor layer 21 below the bottom surface F40btm of the gate electrode 40 is thus suppressed and BTBT in the channel region CH becomes likely to occur.

Further, in the first embodiment, the length L70 from the bottom surface F70btm of the silicide layer 70 to the top surface F70top of the silicide layer 70 is larger than the length Ltn from the bottom surface F40btm of the gate electrode 40 to the height of the top surface F70top of the silicide layer 70. Therefore, the bottom surface F70btm of the silicide layer 70 is provided at a depth (height) equal to the bottom surface F40btm of the gate electrode 40 or a deeper (lower) position. This enables suppression of parasitic BTBT occurring at the lower end E40 of the gate electrode 40 on the source side.

When the bottom surface F70btm of the silicide layer 70 is located at a shallower (higher) position than the bottom surface F40btm of the gate electrode 40, the lower end E40 of the gate electrode 40 does not face the silicide layer 70. In this case, in the vicinity of the lower end E40, parasitic BTBT in which a current flows in a direction different from the arrow A1 is more likely to occur than the BTBT in the channel region CH. Such parasitic BTBT causes deterioration in sub-threshold swing characteristics (hereinafter, also “SS characteristics”).

In contrast thereto, in the first embodiment, because the bottom surface F70btm of the silicide layer 70 is formed at a position equal to or deeper than the bottom surface F40btm of the gate electrode 40, the silicide layer 70 faces the lower end E40 of the gate electrode 40 in the direction D2. Accordingly, parasitic BTBT occurring at the lower end E40 of the gate electrode 40 on the source side can be suppressed.

A manufacturing method of the TFET 100 according to the first embodiment is explained next.

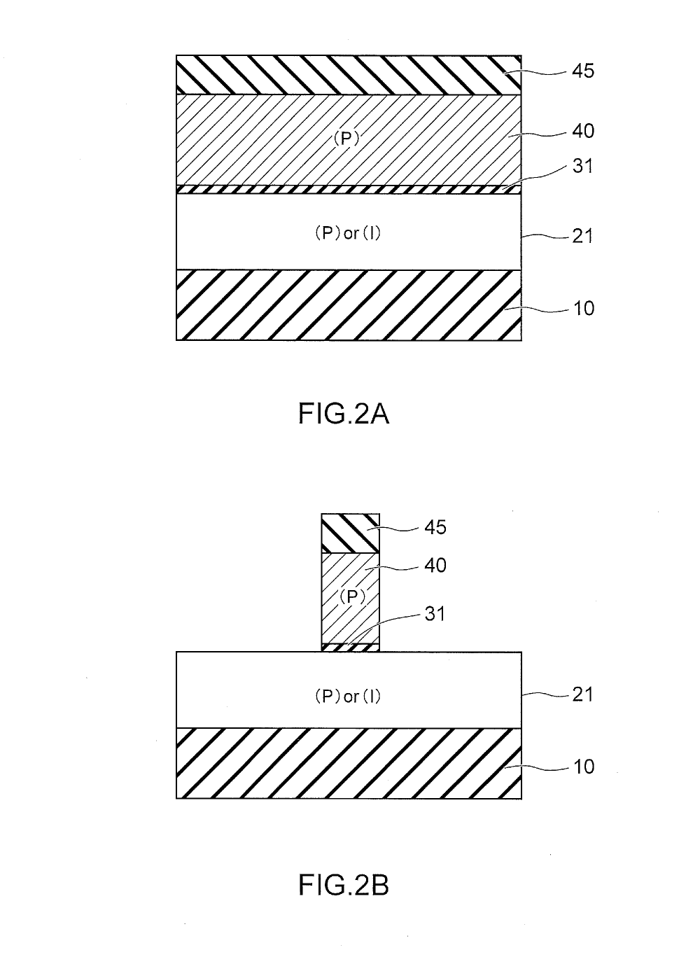

FIGS. 2A to 6B are cross-sectional views showing an example of a manufacturing method of the P-type TFET 100 according to the first embodiment.

First, as shown in FIG. 2A, the first gate dielectric film 31 is formed on the first semiconductor layer 21. The first semiconductor layer 21 can be a SOI layer of a SOI substrate, a SiGe layer of a SiGe-OI substrate, a Ge layer of a Ge-OI substrate, a silicon layer formed of a silicon substrate, or a semiconductor layer using a III-V compound semiconductor substrate. Alternatively, the first semiconductor layer 21 can be a semiconductor layer epitaxially grown on an arbitrary substrate.

The first gate dielectric film 31 can be a thermally-oxidized film obtained by thermally oxidizing the first semiconductor layer 21 or can be a TEOS film, a silicon nitride film (Si₃N₄), SiON film, a high dielectric film such as HfO₂, or the like formed by a CVD (Chemical Vapor Deposition) method.

Next, a material of the gate electrode 40 is deposited on the first gate dielectric film 31 and a material of a hard mask 45 is deposited on the material of the gate electrode 40. The material of the gate electrode 40 is formed of, for example, polysilicon or polysilicon germanium doped with P-type impurities such as boron. Alternatively, the material of the gate electrode 40 can be formed by implanting ions of the P-type impurities after depositing polysilicon or polysilicon germanium. The material of the hard mask 45 is formed of an insulating film such as a silicon nitride film.

Subsequently, the material of the hard mask 45 is processed into a layout pattern of the gate electrode 40 using a lithography technique and a RIE (Reactive Ion Etching) method. The material of the gate electrode 40 and the first gate dielectric film 31 are processed by the RIE method using the hard mask 45 as a mask. A structure shown in FIG. 2B is thereby obtained. A combination of the gate electrode 40 and the first gate dielectric film 31 can be a combination of polysilicon and SiON or a combination of a metal gate and a high dielectric film. When the combination of the gate electrode 40 and the first gate dielectric film 31 is a combination of a metal gate and a high dielectric film, a material of the metal gate can be TiN, TaOx, TaN, or the like and the high dielectric film can be HfOx, HfSiON, HfON, Al₂O₃, or the like. In this case, x is a positive number.

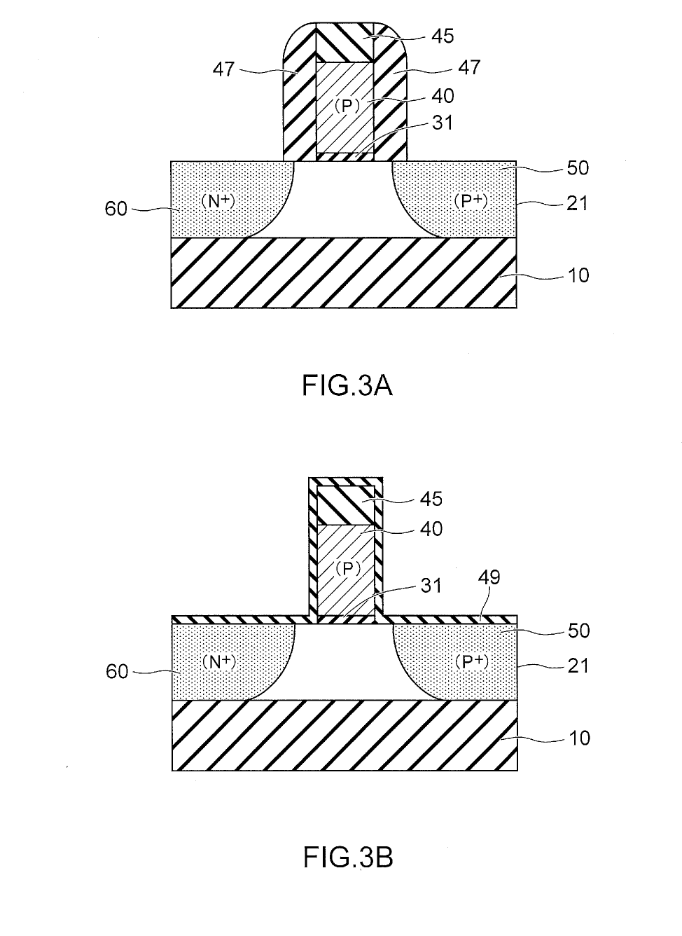

Next, a material of a spacer 47 is deposited on side surfaces of the gate electrode 40 and a top surface of the hard mask 45 using the CVD method. The material of the spacer 47 is an insulating film such as a silicon nitride film. Subsequently, the material of the spacer 47 is anisotropically etched using the RIE method. The spacer 47 is thereby left on the side surfaces of the gate electrode 40 as shown in FIG. 3A.

Next, a drain formation region is covered with a photoresist using the lithography technique. By using the photoresist as a mask, ions of N-type impurities (phosphorous or arsenic, for example) are implanted to the first semiconductor layer 21 in a source formation region. The N-type impurity ions are implanted, for example, at an acceleration energy of about 4 keV and at a concentration of about 1×10¹⁵/cm⁻². After the photoresist is removed, the source formation region is covered with a photoresist using the lithography technique again. Ions of P-type impurities (boron, for example) are implanted to the first semiconductor layer 21 in the drain formation region using the photoresist as a mask. The P-type impurity ions are implanted, for example, at an acceleration energy of about 2 keV and at a concentration of about 1×10¹⁵/cm⁻². Activation annealing is then performed, whereby the P-type drain layer 50 and the N-type source layer 60 are formed as shown in FIG. 3A. The drain layer 50 is provided in a portion of the first semiconductor layer 21 located on one side of the gate electrode 40 and the source layer 60 is provided in a portion of the first semiconductor layer 21 located on the other side of the gate electrode 40.

Next, the spacer 47 is removed using a wet etching method. Subsequently, a liner layer 49 is formed on the first semiconductor layer 21 and the gate electrode 40 as shown in FIG. 3B. The liner layer 49 is formed of an insulating film such as a silicon dioxide film and has a thickness of about 10 nanometers.

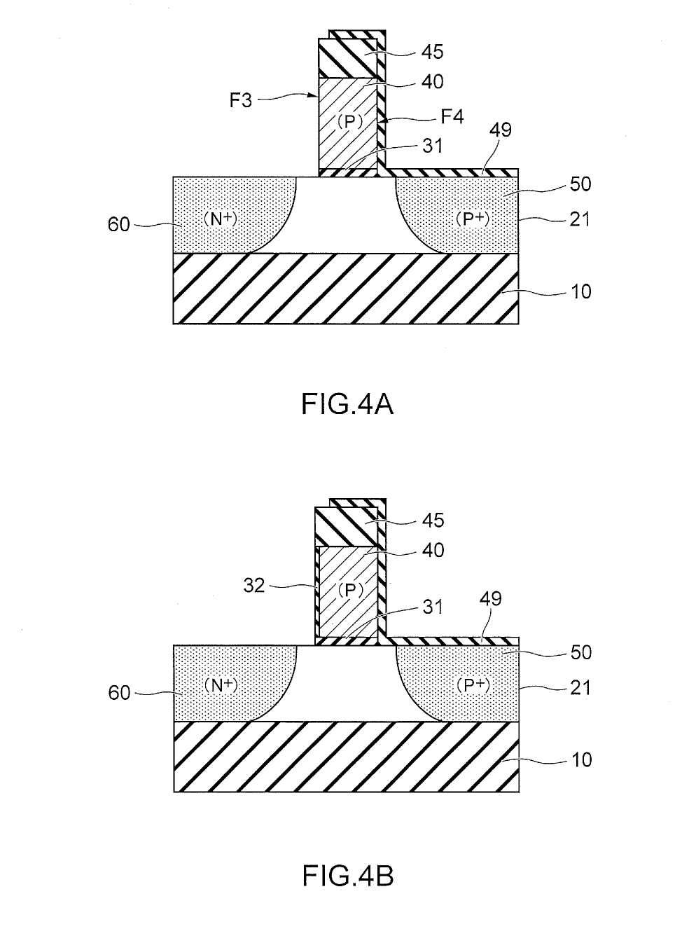

Next, portions of the liner layer 49 provided on the surface of the source layer 60 and the third side surface F3 of the gate electrode 40 are removed using the lithography technique and the wet etching method. The liner layer 49 is thereby left on the surface of the drain layer 50 and the fourth side surface F4 of the gate electrode 40 as shown in FIG. 4A.

Subsequently, the second gate dielectric film 32 is formed on the third side surface F3 of the gate electrode 40 and the source layer 60. The second gate dielectric film 32 can be a thermally-oxidized film obtained by thermally oxidizing the gate electrode 40 or can be a TEOS film, a silicon nitride film (Si₃N₄), SiON film, a high dielectric film such as HfO₂, or the like formed by the CVD method. It is preferable that the film thickness of the second gate dielectric film 32 be equal to or smaller than that of the first gate dielectric film 31.

Next, the second gate dielectric film 32 is etched back using the RIE method or the like, thereby removing the second gate dielectric film 32 located on the source layer 60 while leaving the second gate dielectric film 32 on the third side surface F3 of the gate electrode 40 as shown in FIG. 4B.

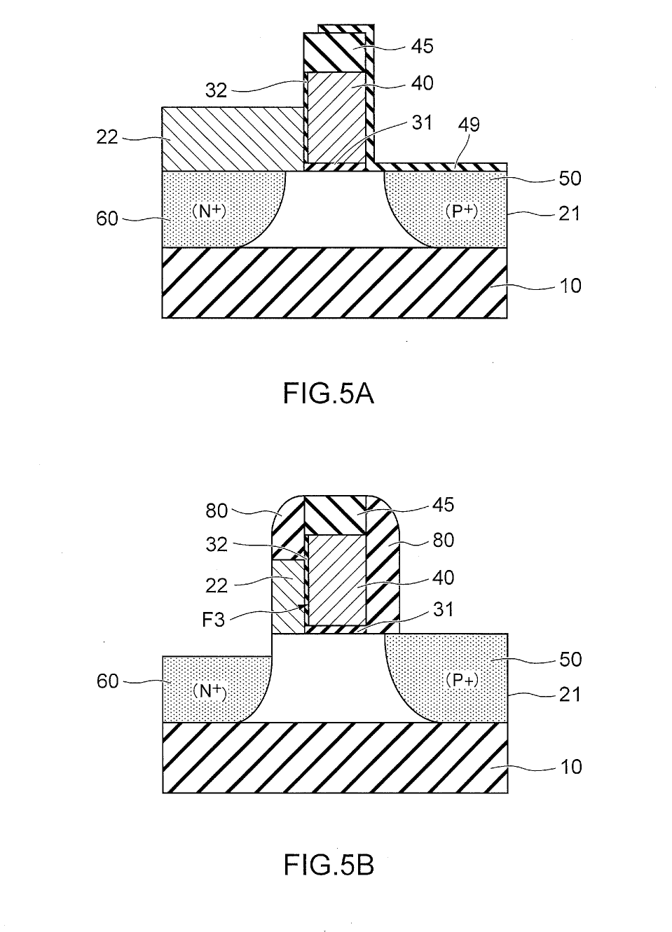

Subsequently, a material of the second semiconductor layer 22 is epitaxially grown on an exposed portion of the first semiconductor layer 21 on the source side as shown in FIG. 5A. The material of the second semiconductor layer 22 grows on the first semiconductor layer 21 to be in contact with the second gate dielectric film 32. An impurity concentration of the material of the second semiconductor layer 22 can be the same as that of the first semiconductor layer 21.

Next, a material of the sidewall film 80 is deposited on the second semiconductor layer 22, the first semiconductor layer 21, and the gate electrode 40. The material of the sidewall film 80 is an insulating film such as a silicon dioxide film and has a thickness of about 20 nanometers. Subsequently, the material of the sidewall film 80 is anisotropically etched using the RIE method, thereby leaving the sidewall film 80 on the side surfaces of the gate electrode 40 as shown in FIG. 5B.

Next, the material of the second semiconductor layer 22 is etched by the RIE method using the sidewall film 80 as a mask. The second semiconductor layer 22 is thereby formed on the third side surface F3 of the gate electrode 40 with the second gate dielectric film 32 interposed therebetween (or via the second gate dielectric film 32). At that time, an upper portion of the first semiconductor layer 21 located under the second semiconductor layer 22 is also etched with etching of the second semiconductor layer 22. The surface of the source layer 60 thereby becomes lower (deeper) than the surface of the first semiconductor layer 21 below the gate electrode 40 as shown in FIG. 5B. As explained later, the bottom surface F70btm of the silicide layer 70 can be formed at a position deeper (lower) than the bottom surface F40btm of the gate electrode 40, furthermore at a position deeper (lower) than the surface F21 of the first semiconductor layer 21.

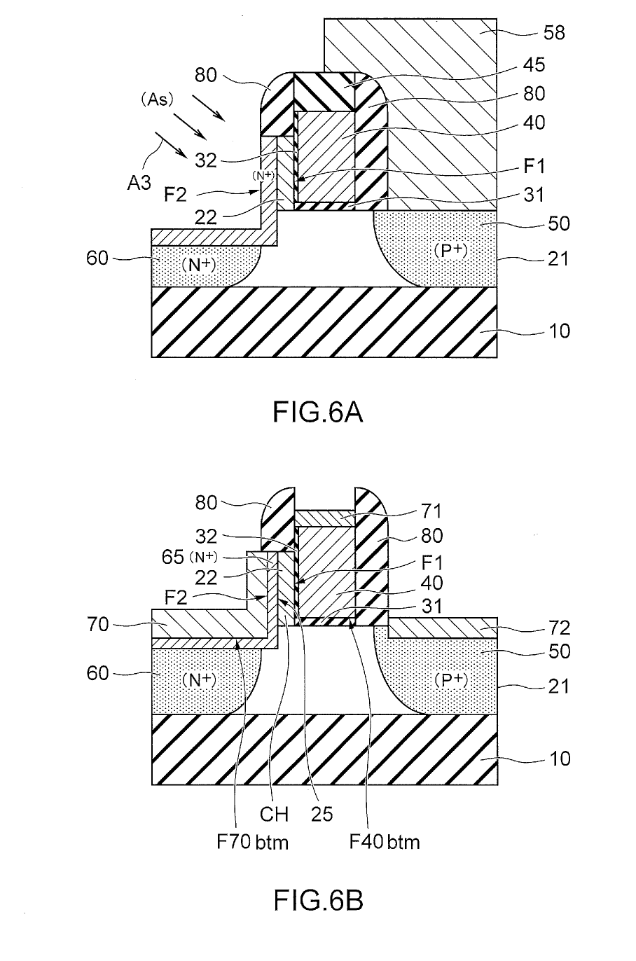

Subsequently, a region of the drain layer 50 is covered with a photoresist 58 using the lithography technique as shown in FIG. 6A. Next, ions of N-type impurities are implanted toward the second side surface F2 of the second semiconductor layer 22. The second side surface F2 is one of the side surfaces of the second semiconductor layer 22 located on the opposite side to the first side surface F1 facing the gate electrode 40. The impurity ions are implanted, for example, at an acceleration energy of about 1 keV and at a concentration of about 1×10¹⁵/cm⁻². At that time, an implantation direction of the impurity ions is inclined to the source side from a direction orthogonal to the surface of the first semiconductor layer 21 as shown by an arrow A3 in FIG. 6A. The impurity ions are implanted in the direction of the arrow A3 toward the second side surface F2 of the second semiconductor layer 22. The N-type impurities thus can be introduced substantially uniformly along the second side surface F2 of the second semiconductor layer 22 as shown in FIG. 6A. Next, activation annealing is performed, thereby activating the N-type impurities in the second semiconductor layer 22.

Subsequently, the photoresist 58 is removed and the hard mask 45 is removed. Accordingly, a top surface of the gate electrode 40 is exposed. Next, a metal layer such as Ni, Co, or Ti is deposited on the source layer 60, the gate electrode 40, and the drain layer 50 using a PVD (Physical Vapor Deposition) method. By causing the metal layer and silicon to react with each other, the silicide layers 70 to 72 are formed on the source layer 60, the gate electrode 40, and the drain layer 50, respectively, as shown in FIG. 6B. The silicide layers 70 to 72 can be, for example, TiSi, Co₂Si, NiSi, NiSi₂, or NiPtSi. At that time, the silicide layer 70 is formed also on the second side surface F2 of the second semiconductor layer 22. Because the silicide layer 70 is formed by a reaction between the metal and the silicon, the N-type impurities in a region of the second side surface F2 of the second semiconductor layer 22 are segregated along the silicide layer 70 when the silicide layer 70 is formed along the second side surface F2. That is, the N-type impurities are segregated into a narrow region along the second side surface F2 of the second semiconductor layer 22 to form the high-concentration layer 65 in which the impurity concentration is quite high. The high-concentration layer 65 is adjacent to a region (the channel region CH) in the second semiconductor layer 22 on the side of the first side surface F1 and forms the junction part (PN junction part or PI junction part) 25. The high-concentration layer 65 is formed also on the surface of the source layer 60.

As explained with reference to FIG. 5B, the upper portion of the first semiconductor layer 21 is recessed in such a manner that the surface of the source layer 60 becomes lower (deeper) than the surface of the first semiconductor layer 21 below the gate electrode 40. Therefore, when the silicide layer 70 is formed on the source layer 60, the bottom surface F70btm of the silicide layer 70 can be formed at a deeper (lower) position than the bottom surface F40btm of the gate electrode 40.

Thereafter, the interlayer dielectric film 90, contacts, wires, and the like are formed, whereby the TFET 100 shown in FIG. 1 is completed.

The TFET 100 according to the first embodiment has the channel region CH and the high-concentration layer 65 extending along the third side surface F3 of the gate electrode 40. The high-concentration layer 65 is formed by segregating impurities in a silicide process and the impurity concentration thereof is equal to or higher than that of the source layer 60. Therefore, the junction part 25 has quite a steep impurity concentration gradient. Accordingly, BTBT in the channel region CH becomes likely to occur and a relatively-large on-current is enabled to flow.

In the first embodiment, the silicide layer 70 is provided to be in contact also with the high-concentration layer 65 located on the second side surface F2 of the second semiconductor layer 22. By thus forming the silicide layer 70 also on the second side surface F2 of the second semiconductor layer 22, impurities in the high-concentration layer 65 can be segregated to increase the impurity concentration. Furthermore, the source electrode can be connected with a low resistance to the high-concentration layer 65 on the second side surface F2 of the second semiconductor layer 22 with the silicide layer 70 interposed therebetween (or via the silicide layer 70). This causes BTBT in the channel region CH to be more likely to occur. A current becomes easy to flow in the channel region CH and an on-current can be further increased.

According to the first embodiment, the film thickness of the second gate dielectric film 32 is formed to be equal to or smaller than that of the first gate dielectric film 31. Accordingly, an electric field from the gate electrode 40 becomes more likely to be applied to the channel region CH of the second semiconductor layer 22 than to the first semiconductor layer 21 under the second semiconductor layer 22. As a result, parasitic BTBT occurring in the first semiconductor layer 21 below the bottom surface F40btm of the gate electrode 40 can be suppressed and BTBT in the channel region CH can be made more likely to occur.

In the first embodiment, the bottom surface F70btm of the silicide layer 70 is located at a position equal to or deeper than the bottom surface F40btm of the gate electrode 40. This enables suppression of parasitic BTBT occurring at the lower end E40 of the gate electrode 40 on the source side.

### Second Embodiment

A second embodiment is different from the first embodiment in the manufacturing method. In a manufacturing method according to the second embodiment, the gate electrode 40 is formed after a silicide process.

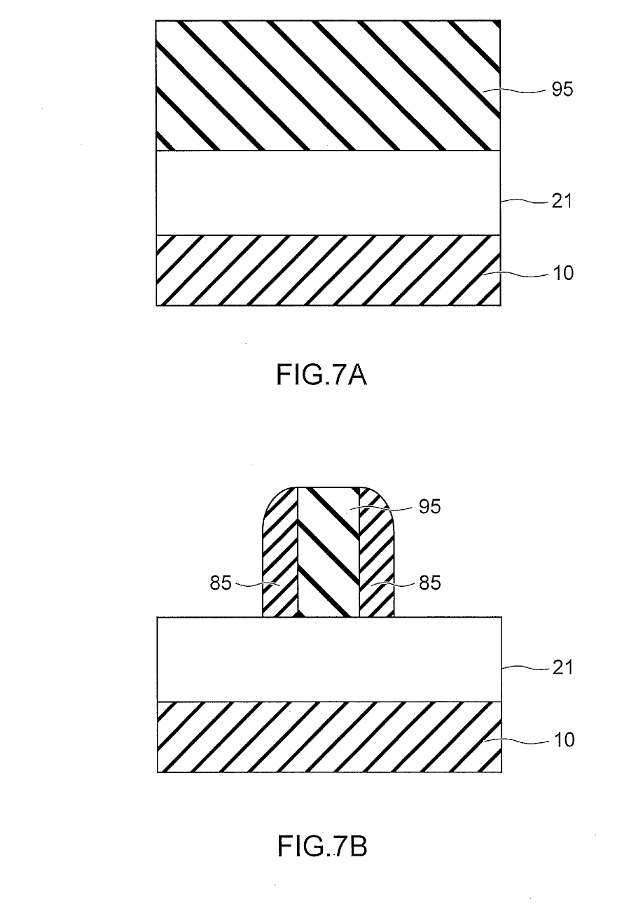

FIGS. 7A to 11 are cross-sectional views showing an example of the manufacturing method of the TFET 100 according to the second embodiment.

First, as shown in FIG. 7A, a material of a sacrifice gate electrode 95 is formed on the first semiconductor layer 21. The material of the sacrifice gate electrode 95 is formed of an insulating film such as a silicon nitride film. Next, the material of the sacrifice gate electrode 95 is processed into a layout pattern of the gate electrode 40 using the lithography technique and the RIE method. Subsequently, a material of the sidewall film 85 is deposited on the sacrifice gate electrode 95 and the first semiconductor layer 21. The material of the sidewall film 85 is an insulating film such as a silicon dioxide film. Further, the material of the sidewall film 85 is anisotropically etched using the RIE method. The sidewall film 85 is thereby formed on side surfaces of the sacrifice gate electrode 95 as shown in FIG. 7B.

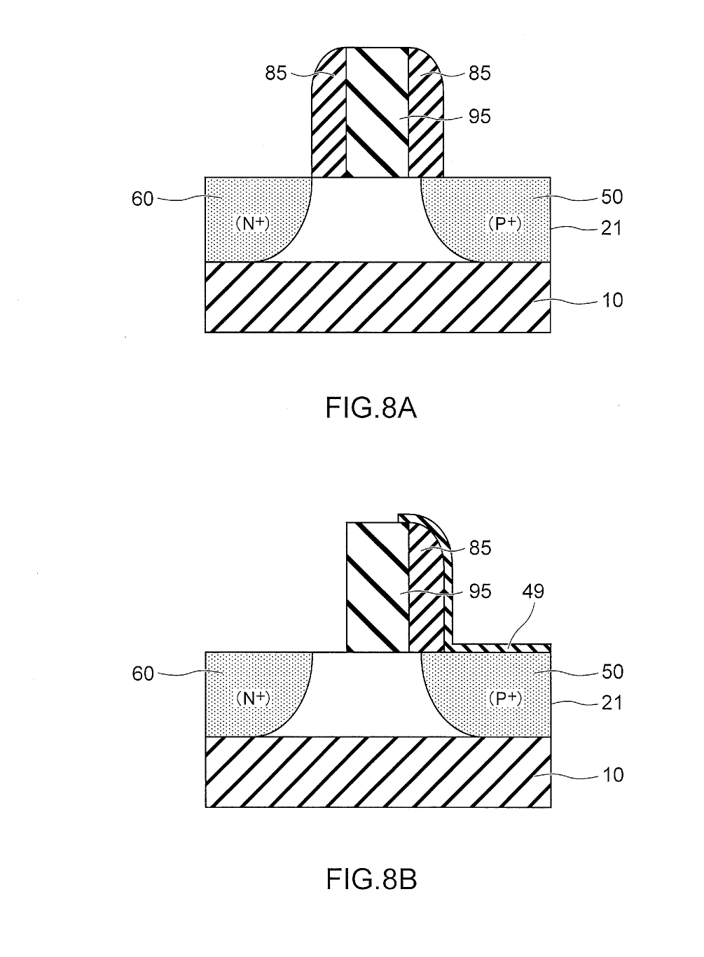

Next, as shown in FIG. 8A, the P-type drain layer 50 and the N-type source layer 60 are formed using the lithography technique and an ion implantation method. Formation processes of the drain layer 50 and the source layer 60 can be identical to those of the drain layer 50 and the source layer 60 in the first embodiment.

Subsequently, the liner layer 49 is formed on the first semiconductor layer 21 and the sacrifice gate electrode 95. The liner layer 49 is formed of an insulating film such as a silicon dioxide film and has a thickness of about 10 nanometers. Next, as shown in FIG. 8B, the liner layer 49 on the source layer 60 is removed using the lithography technique and the wet etching method with the liner layer 49 on the drain layer 50 left remained. Subsequently, an exposed portion of the sidewall film 85 on the source side is removed.

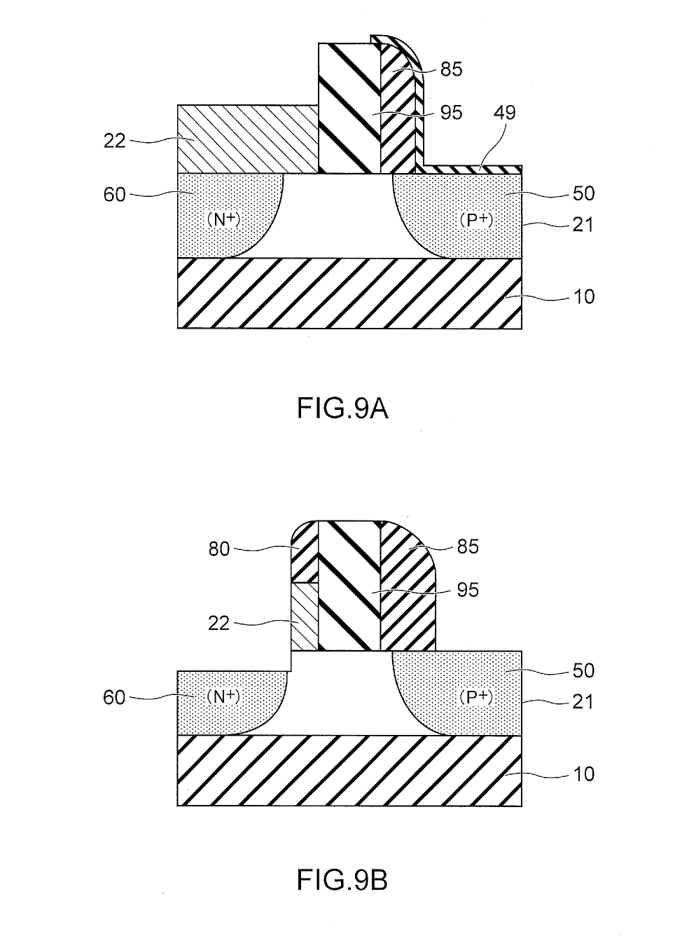

Next, as shown in FIG. 9A, a material of the second semiconductor layer 22 is epitaxially grown on an exposed portion of the first semiconductor layer 21 on the source side. The material of the second semiconductor layer 22 grows on the first semiconductor layer 21 along one side surface of the sacrifice gate electrode 95. The impurity concentration of the material of the second semiconductor layer 22 can be the same as that of the first semiconductor layer 21.

Subsequently, a material of the sidewall film 80 is deposited on the second semiconductor layer 22, the first semiconductor layer 21, and the sacrifice gate electrode 95. The material of the sidewall film 80 is, for example, an insulating film such as a silicon dioxide film having a thickness of about 20 nanometers. Next, the material of the sidewall film 80 is anisotropically etched using the RIE method, thereby leaving the sidewall film 80 on the side surfaces of the sacrifice gate electrode 95 as shown in FIG. 9B.

Subsequently, the second semiconductor layer 22 formed on the source layer 60 is etched by the RIE method using the sidewall film 80 as a mask. The second semiconductor layer 22 is thereby formed on the first semiconductor layer 21 along one side surface of the sacrifice gate electrode 95. With etching of the material of the second semiconductor layer 22, an upper portion of the first semiconductor layer 21 located under the second semiconductor layer 22 is also etched. The surface of the source layer 60 thereby becomes lower (deeper) than the surface of the first semiconductor layer 21 below the gate electrode 40 as shown in FIG. 9B. As explained later, the bottom surface F70btm of the silicide layer 70 can be formed at a position deeper (lower) than the bottom surface F40btm of the gate electrode 40.

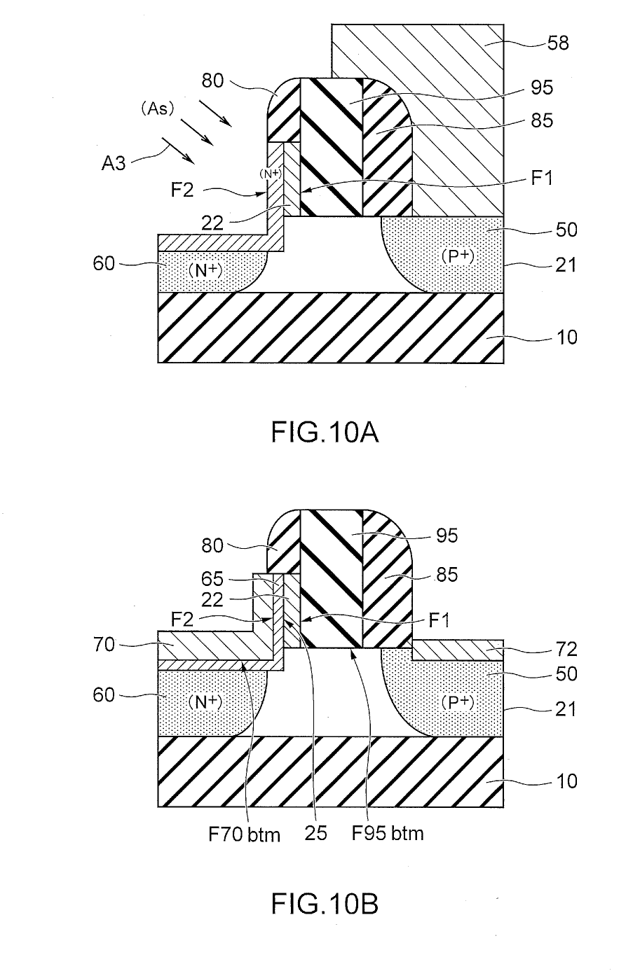

Next, as shown in FIG. 10A, a region of the drain layer 50 is covered with the photoresist 58 using the lithography technique. Subsequently, ions of N-type impurities are implanted toward the second side surface F2 of the second semiconductor layer 22. The second side surface F2 is one of the side surfaces of the second semiconductor layer 22 on the opposite side to the first side surface F1 facing the sacrifice gate electrode 95. An ion implantation process can be identical to that explained with reference to FIG. 6A. The N-type impurities thereby can be introduced substantially uniformly along the second side surface F2 of the second semiconductor layer 22 as shown in FIG. 10A. Next, activation annealing is performed to activate the N-type impurities in the second semiconductor layer 22.

Subsequently, the photoresist 58 is removed. Next, a metal layer such as Ni, Co, or Ti is deposited on the source layer 60, the sacrifice gate electrode 95, and the drain layer 50 using the PVD method. By causing the metal layer and silicon to react with each other, the silicide layers 70 and 72 are formed on the source layer 60 and the drain layer 50, respectively, as shown in FIG. 10B. The silicide layers 70 and 72 can be identical to those in the first embodiment. At that time, the silicide layer 70 is formed also on the second side surface F2 of the second semiconductor layer 22. When the silicide layer 70 is formed along the second side surface F2, the N-type impurities are segregated into a narrow region along the second side surface F2 of the second semiconductor layer 22 to form the high-concentration layer 65 in which the impurity concentration is quite high. The high-concentration layer 65 is adjacent to a region (the channel region CH) in the second semiconductor layer 22 on the side of the first side surface F1 and forms the junction part (PN junction part or PI junction part) 25. When the silicide layer 70 is formed on the source layer 60, the bottom surface F70btm of the silicide layer 70 can be formed at a depth (height) equal to a bottom surface F95btm of the sacrifice gate electrode 95 or a deeper (lower) position.

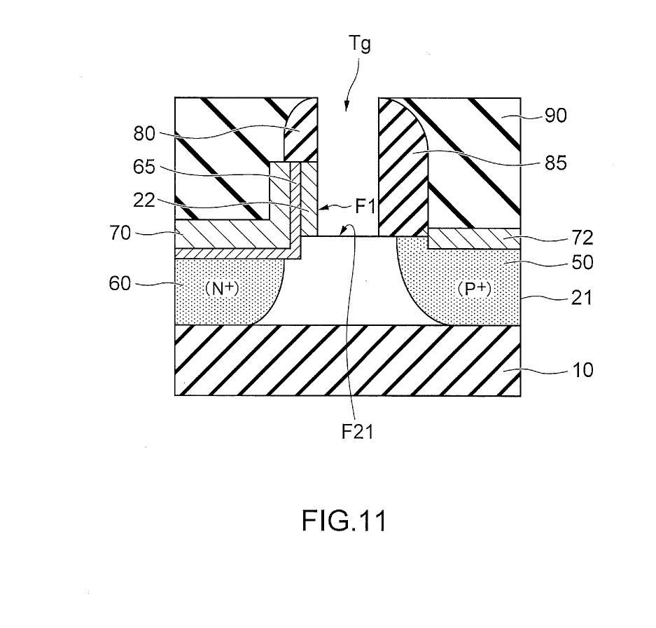

Subsequently, a material of the interlayer dielectric film 90 is deposited on the sacrifice gate electrode 95 and the silicide layers 70 and 72. The material of the interlayer dielectric film 90 is formed of an insulating film such as a silicon dioxide film (a TEOS film, for example). Next, the material of the interlayer dielectric film 90 is polished using a CMP (Chemical Mechanical Polishing) method to expose a top surface of the sacrifice gate electrode 95. Subsequently, the sacrifice gate electrode 95 is selectively removed using the wet etching method. A gate trench Tg is thereby formed as shown in FIG. 11. In the inside of the gate trench Tg, the surface F21 of the first semiconductor layer 21 and the first side surface F1 of the second semiconductor layer 22 are exposed.

Next, in the gate trench Tg, the first gate dielectric film 31 is formed on the surface F21 of the first semiconductor layer 21 and the second gate dielectric film 32 is formed on the first side surface F1 of the second semiconductor layer 22. The first gate dielectric film 31 and the second gate dielectric film 32 can be formed, for example, simultaneously by a thermal oxidation method. In this case, materials and film thicknesses of the first gate dielectric film 31 and the second gate dielectric film 32 are equal. A material of the gate electrode 40 is further embedded in the gate trench Tg. The gate electrode 40 is thereby formed to be in contact with the first and second gate dielectric films 31 and 32. The material of the gate electrode 40 can be identical to that of the gate electrode 40 in the first embodiment. However, because the gate electrode 40 is formed after formation of the silicide layers 70 and 72 in the second embodiment, the material of the gate electrode 40 can be alternatively a metal having a lower melting point than that of the metal used in formation of the silicide layers 70 and 72.

Contacts, wires, and the like are then formed, whereby the TFET 100 shown in FIG. 1 is completed.

As described above, the gate electrode 40 can be formed after formation of the silicide layers 70 and 72. This enables the gate electrode 40 to be formed of a metal having a lower melting point than that of the metal used for the silicide layers 70 and 72. The configuration of the second embodiment may be identical to that of the first embodiment. Therefore, the second embodiment can attain identical effects as those of the first embodiment. However, in the second embodiment, because the first and second gate dielectric films 31 and 32 have substantially the same film thickness, it is difficult to obtain effects attainable by making the film thickness of the second gate dielectric film 32 thinner than that of the first gate dielectric film 31.

### Third Embodiment

The TFET 100 according to a third embodiment has the same configuration as that according to the first embodiment. In a manufacturing method according to the third embodiment, the gate electrode 40 is formed after a silicide process similarly in that according to the second embodiment. However, by the manufacturing method according to the third embodiment, a film thickness of the second gate dielectric film 32 can be different from that of the first gate dielectric film 31.

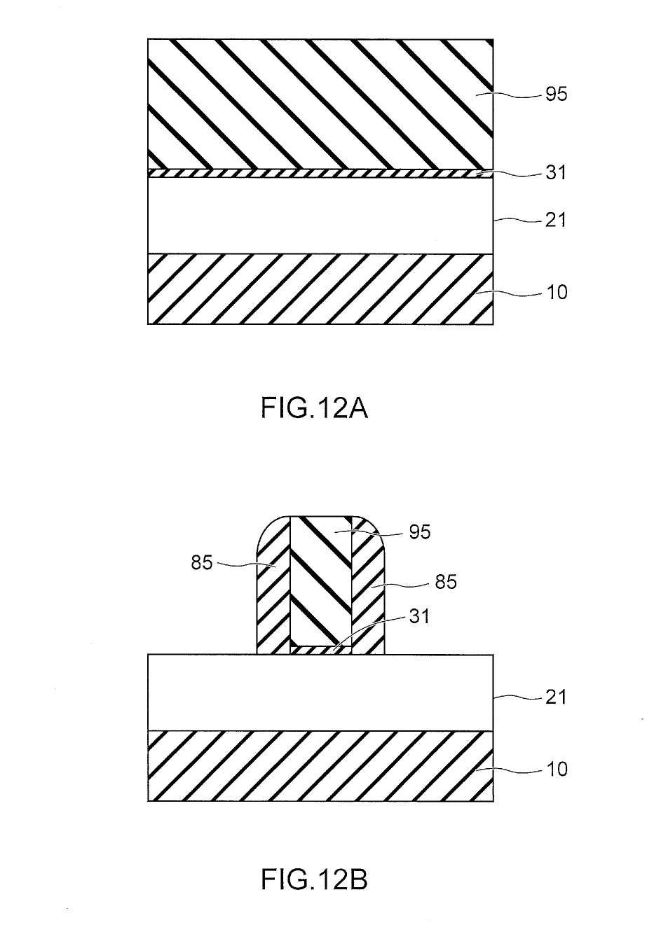

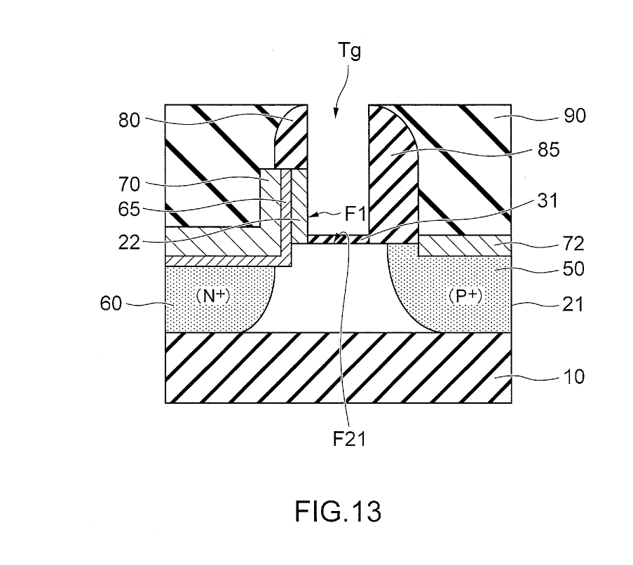

FIGS. 12A to 13 are cross-sectional views showing an example of the manufacturing method of the TFET 100 according to the third embodiment.

First, as shown in FIG. 12A, the first gate dielectric film 31 is formed on the first semiconductor layer 21. Configurations of the first semiconductor layer 21 and the first gate dielectric film 31 can be identical to those in the first embodiment. The first gate dielectric film 31 is formed to be thicker than the second gate dielectric film 32 that is formed later.

Next, a material of the sacrifice gate electrode 95 is formed on the first gate dielectric film 31. The material of the sacrifice gate electrode 95 can be identical to that of the sacrifice gate electrode 95 in the second embodiment. Subsequently, the material of the sacrifice gate electrode 95 is processed in a layout pattern of the gate electrode 40 using the lithography technique and the RIE method. At that time, the first gate dielectric film 31 is also processed similarly to the sacrifice gate electrode 95.

The sidewall film 85 is then formed on the side surfaces of the sacrifice gate electrode 95. A structure shown in FIG. 12B is thereby obtained.

Processes explained with reference to FIGS. 8A to 11 are then performed. A structure shown in FIG. 13 is thereby obtained.

Next, in the gate trench Tg, the second gate dielectric film 32 is formed on the first side surface F1 of the second semiconductor layer 22. The second gate dielectric film 32 can be formed, for example, by the thermal oxidation method. A film thickness of the second gate dielectric film 32 is formed to be smaller than that of the first gate dielectric film 31. A material of the gate electrode 40 is further embedded in the gate trench Tg. The material of the gate electrode 40 can be identical to that of the gate electrode 40 in the second embodiment. Therefore, the material of the gate electrode 40 can be a metal having a lower melting point than that of the metal used in formation of the silicide layers 70 and 72.

Contacts, wires, and the like are then formed, whereby the TFET 100 shown in FIG. 1 is completed.

According to the third embodiment, the gate electrode 40 is formed after formation of the silicide layers 70 and 72. Therefore, the gate electrode 40 can be formed of a metal having a lower melting point than that of the metal used for the silicide layers 70 and 72. Therefore, the third embodiment can attain identical effects as those of the second embodiment.

Furthermore, according to the third embodiment, the film thickness of the second gate dielectric film 32 can be smaller than that of the first gate dielectric film 31 similarly in the first embodiment. Therefore, the third embodiment can attain identical effects as those of the first embodiment.

While a P-type TFET is explained in the above embodiments, the embodiments can be easily applied also to an N-type TFET by changing conductivity types of impurities. The N-type TFET becomes an on-state when a gate voltage is higher than a threshold voltage with reference to a source voltage and becomes an off-state when a gate voltage is lower than the threshold voltage. For example, in the N-type TFET, 0 volt is applied to a source and the N-type TFET is brought to an on-state by setting the gate voltage to a positive voltage (1 volt, for example) while being brought to an off-state by setting the gate voltage to 0 volt. Even in such an N-type TFET, the effects of the above embodiments are not lost.

In an N-type TFET, the high-concentration layer 65 is a high-concentration P-type impurity layer. The high-concentration P-type impurity layer is formed by segregating P-type impurities when the silicide layer 70 is formed. For example, when boron is used as the P-type impurities, it is preferable that a metal used in formation of the silicide layer 70 be cobalt in order to segregate boron. By using cobalt in formation of the silicide layer 70, boron becomes likely to be segregated along the silicide layer 70. In this case, the high-concentration layer 65 is a high-concentration P-type impurity layer containing boron and the silicide layer 70 is a cobalt silicide. In this way, the above embodiments can be applied also to the N-type TFET.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first semiconductor layer;
a second semiconductor layer on the first semiconductor layer, the second semiconductor layer having a first side surface and a second side surface on an opposite side to the first side surface;
a first gate dielectric film on the first semiconductor layer;
a second gate dielectric film on the first side surface of the second semiconductor layer;
a gate electrode having a bottom surface facing a surface of the first semiconductor layer via the first gate dielectric film, and a third side surface facing the first side surface of the second semiconductor layer via the second gate dielectric film;
a first diffusion layer of a first conductivity type in a region of the second semiconductor layer on a side of the second side surface, the first diffusion layer forming a junction part with a region of the second semiconductor layer on a side of the first side surface;
a silicide layer on the second side surface of the second semiconductor layer, the silicide layer connecting to the first diffusion layer;
a source layer of the first conductivity type in the first semiconductor layer on a side of the third side surface of the gate electrode, the source layer being electrically connected to the first diffusion layer and the silicide layer; and
a drain layer of a second conductivity type in the first semiconductor layer on a side of a fourth side surface of the gate electrode on an opposite side to the third side surface.

2. The device of claim 1, wherein a length along the second side surface from a bottom surface of the silicide layer to a top surface of the silicide layer is larger than a length along the third side surface from the bottom surface of the gate electrode to the top surface of the silicide layer.

3. The device of claim 1, wherein a bottom surface of the silicide layer is located at a position deeper than the surface of the first semiconductor layer.

4. The device of claim 1, wherein a film thickness of the second gate dielectric film is equal to or smaller than that of the first gate dielectric film.

5. The device of claim 1, wherein a film thickness of the second gate dielectric film is smaller than that of the first gate dielectric film.

6. The device of claim 1, wherein the gate electrode is formed of a metal having a lower melting point than that of a metal contained in the silicide layer.

7. The device of claim 1, wherein an impurity concentration of the first diffusion layer is high in a vicinity of the second side surface and decreases from the second side surface toward the first side surface.

8. The device of claim 1, wherein
the region of the second semiconductor layer on the side of the first side surface is a second conductivity-type semiconductor or an intrinsic semiconductor, and
the junction part is a PN junction or a PI junction along the second side surface of the second semiconductor layer.

9. The device of claim 1, wherein an impurity concentration of the first diffusion layer is higher than that of the source layer.

10. The device of claim 1, wherein the first diffusion layer and the silicide layer are located also on the source layer.

11. The device of claim 1, wherein the first diffusion layer is a diffusion layer containing arsenic as impurities.

12. The device of claim 1, wherein
the first diffusion layer is a diffusion layer containing boron as impurities, and
the silicide layer includes a cobalt silicide.

13. A manufacturing method of a semiconductor device, the method comprising:
forming a first gate dielectric film on a first semiconductor layer,
forming a gate electrode on the first gate dielectric film;
forming a source layer of a first conductivity type in the first semiconductor layer on one side of the gate electrode;
forming a drain layer of a second conductivity type in the first semiconductor layer on other side of the gate electrode;
forming a second gate dielectric film on a side surface of the gate electrode on the one side;
forming a second semiconductor layer of which a first side surface faces the side surface of the gate electrode via the second gate dielectric film;
introducing first conductivity-type impurities to a second side surface of the second semiconductor layer on an opposite side to the first side surface; and
forming a silicide layer on the second side surface of the second semiconductor layer, to which the first conductivity-type impurities are introduced.

14. The method of claim 13, wherein
formation of the second semiconductor layer comprises:
growing a material of the second semiconductor layer on the first semiconductor layer to be in contact with the second gate dielectric film; and
etching the material of the second semiconductor layer using a sidewall film as a mask, the sidewall film being provided on the side surface of the gate electrode via the second gate dielectric film, and removing also an upper portion of the first semiconductor layer in a formation region of the source layer.

15. The method of claim 14, wherein a bottom surface of the silicide layer is formed at a position deeper than a surface of the first semiconductor layer.

16. The method of claim 13, wherein a thickness of the second gate dielectric film is equal to or smaller than that of the first gate dielectric film.

17. The method of claim 13, wherein the first conductivity-type impurities are segregated along the silicide layer during formation of the silicide layer.

18. A manufacturing method of a semiconductor device, the method comprising:
forming a sacrifice gate electrode above a first semiconductor layer;
forming a source layer of a first conductivity type in the first semiconductor layer on one side of the sacrifice gate electrode;
forming a drain layer of a second conductivity type in the first semiconductor layer on other side of the sacrifice gate electrode;
forming a second semiconductor layer of which a first side surface faces a side surface of the sacrifice gate electrode on the one side;
introducing first conductivity-type impurities to a second side surface of the second semiconductor layer on an opposite side to the first side surface;
forming a silicide layer on the second side surface of the second semiconductor layer, to which the first conductivity-type impurities are introduced;
removing the sacrifice gate electrode after formation of the silicide layer to form a gate trench; and
forming a gate electrode in the gate trench to be in contact with a first gate dielectric film formed on the first semiconductor layer and with a second gate dielectric film formed on the first side surface of the second semiconductor layer.

19. The method of claim 18, further comprising forming the first gate dielectric film on the first semiconductor layer and the second gate dielectric film on the first side surface of the second semiconductor layer in the gate trench, after removing the sacrifice gate electrode.

20. The method of claim 18, further comprising:
forming the first gate dielectric film on the first semiconductor layer, before formation of the sacrifice gate electrode; and
forming the second gate dielectric film on the first side surface of the second semiconductor layer in the gate trench, after removing the sacrifice gate electrode.
